(19) United States
(12) Patent Application Publication
(10) Pub. No.: US 2017/0338198 A1
(43) Pub. Date: Nov. 23, 2017

(54) DISPLAY DEVICE INCLUDING AN ANISOTROPIC CONDUCTIVE FILM, AND MANUFACTURING METHOD OF THE ANISOTROPIC CONDUCTIVE FILM

(71) Applicant: SAMSUNG DISPLAY CO., LTD., Yongin-si (KR)

(72) Inventors: Eui Yun JANG, Seoul (KR); Dong-Hee PARK, Yongin-si (KR); Cheol Geun AN, Yongin-si (KR); Ji Hoon OH, Daegu (KR); Chung-Seok LEE, Hwaseong-si (KR); Jeong Ho HWANG, Cheonan-si (KR)

(21) Appl. No.: 15/365,979

(22) Filed: Dec. 1, 2016

(30) Foreign Application Priority Data
May 17, 2016 (KR) 10-2016-0060271

(51) Int. Cl. H01L 23/00

(52) U.S. Cl. CPC H01L 24/29; H01L 24/14; H01L 24/27; H01L 24/05; H01L 2224/27618; H01L 2224/29028; H01L 2224/0401

(57) ABSTRACT

A display device including pads; an anisotropic conductive film on the pads; and a connection member bonded to the pads through the film, the connection member including bumps, the film includes a supporting layer including a plurality of conductive particles having a part protruded from a first and second surface of the support layer; a first adhesive layer contacting the first surface and the part of each conductive particle protruding from the first surface; and a second adhesive layer contacting the second surface and the part of each conductive particle protruding from the second surface, and wherein the first or second adhesive layer is positioned at both of a first and second region of the display device, the first region being a region in which the pads and the bumps are overlapped and the second region being a region in which the pads and the bumps are not overlapped.

### CROSS-REFERENCE TO RELATED APPLICATION

Korean Patent Application No. 10-2016-0060271, filed on May 17, 2016, in the Korean Intellectual Property Office, and entitled: “Display Device Including An Anisotropic Conductive Film, and Manufacturing Method of the Anisotropic Conductive Film,” is incorporated by reference herein in its entirety.

### BACKGROUND

### 1. Field

Embodiments relate to a display device including an anisotropic conductive film and a manufacturing method of an anisotropic conductive film.

### 2. Description of the Related Art

A display device displaying an image (such as a liquid crystal display and an organic light emitting diode display) includes a display panel. To control the operation of the display panel, a pad portion for input and output of a signal may be disposed in the display panel, and the pad portion may be bonded with an integrated circuit chip or a flexible printed circuit board.

For an electrical connection and physical coupling between the integrated circuit chip or the flexible printed circuit board and the pad portion, an anisotropic conductive film (ACF) may be used. The anisotropic conductive film (as a film in which conductive particles are disposed in an insulating layer) has conductivity in a thickness direction of the film and is insulative in a surface or lateral direction of the film.

The above information disclosed in this Background section is only for enhancement of understanding of the background of the invention and therefore it may contain information that does not form the prior art that is already known in this country to a person of ordinary skill in the art.

### SUMMARY

Embodiments are directed to a display device including an anisotropic conductive film and a manufacturing method of an anisotropic conductive film.

The embodiments may be realized by providing a display device including a pad portion positioned on a substrate, the pad portion including a plurality of pads; an anisotropic conductive film positioned on the pad portion; and a connection member bonded to the pad portion through the anisotropic conductive film, the connection member including a plurality of bumps, wherein the anisotropic conductive film includes a supporting layer including a plurality of conductive particles, each of the conductive particles having a part protruded from a first surface of the supporting layer and a part protruded from a second surface of the supporting layer; a first adhesive layer contacting the first surface of the supporting layer and the part of each conductive particle protruding from the first surface; and a second adhesive layer contacting the second surface of the supporting layer and the part of each conductive particle protruding from the second surface, and wherein at least one of the first adhesive layer and the second adhesive layer is positioned at both of a first region of the display device and a second region of the display device, the first region being a region in which the pads and the bumps are overlapped and the second region being a region in which the pads and the bumps are not overlapped.

The supporting layer may be formed of a material that is different from a material of the first adhesive layer and a material of the second adhesive layer.

The supporting layer may include at least one of polyimide, polyethylene terephthalate, nylon 6, polyvinylidene fluoride, polycarbonate, polybutylene succinate, or polyethylene.

A melting point of the supporting layer may be higher than a curing point of the first adhesive layer and a curing point of the second adhesive layer.

An interval between the conductive particles adjacent to one another in a first direction may be uniform in the first region and the second region.

An interval between the conductive particles adjacent to one another in a second direction may be uniform in the first region and the second region, the second direction crossing the first direction.

The plurality of conductive particles may be arranged as a rectangle or a rhombus in a plan view.

A diameter of the plurality of conductive particles may be larger than a thickness of the supporting layer.

A part of the first adhesive layer in the first region may be thinner than a part of the first adhesive layer in the second region.

A part of the second adhesive layer in the first region may be thinner than a part of the second adhesive layer in the second region.

The embodiments may be realized by providing a method for manufacturing an anisotropic conductive film, the method including arranging conductive particles at a non-cured resin layer; curing the resin layer to fix the conductive particles in the cured resin layer; and etching the cured resin layer to form a supporting member such that a part of the conductive particles are exposed.

Etching the cured resin layer may include exposing the part of the conductive particles on at least one surface of the supporting member.

The etching the cured resin layer may include reactivity ion etching.

The supporting layer may include at least one of polyimide, polyethylene terephthalate, nylon 6, polyvinylidene fluoride, polycarbonate, polybutylene succinate, or polyethylene.

The method may further include forming an adhesive layer on at least one surface of the supporting member.

The adhesive layer may be formed to be in contact with the exposed part of the conductive particles.

Forming the adhesive layer may include laminating a non-cured resin layer on the supporting member.

The adhesive layer may be formed of a material that is different from a material of the supporting layer.

A melting point of the supporting layer may be higher than a curing point of the adhesive layer.

The supporting layer may be formed to have a thickness that is smaller than a diameter of each conductive particle.

### BRIEF DESCRIPTION OF THE DRAWINGS

Features will be apparent to those of skill in the art by describing in detail exemplary embodiments with reference to the attached drawings in which:

FIG. 1 illustrates a plan view schematically showing a display device according to an exemplary embodiment.

FIG. 2 illustrates an enlarged plan view showing a region A in FIG. 1.

FIG. 3 illustrates a cross-sectional view showing an exemplary embodiment taken along a line III-III′ of FIG. 2.

FIG. 4 illustrates a cross-sectional view showing an exemplary embodiment taken along a line of FIG. 2.

FIG. 5 illustrates a cross-sectional view showing an exemplary embodiment taken along a line of FIG. 2.

FIG. 6 illustrates a cross-sectional view showing an exemplary embodiment of a region A in FIG. 1.

FIG. 7 illustrates a cross-sectional view showing an exemplary embodiment of a pixel area in FIG. 1.

FIG. 8 illustrates a cross-sectional view showing an exemplary embodiment of a region A in FIG. 1.

FIG. 9 illustrates a cross-sectional view showing an exemplary embodiment of a pixel area in FIG. 1.

FIG. 10 illustrates a cross-sectional view of an anisotropic conductive film according to an exemplary embodiment of the present invention.

FIG. 11 to FIG. 14 illustrate process cross-sectional views of stages in a manufacturing method of an anisotropic conductive film shown in FIG. 10.

FIG. 15 illustrates a cross-sectional view of an anisotropic conductive film according to an exemplary embodiment.

FIG. 16 illustrates a cross-sectional view of an anisotropic conductive film according to an exemplary embodiment.

FIG. 17 and FIG. 18 illustrate each plan views showing an arrangement of conductive particles according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and “include” and variations such as “comprises”, “includes”, “including”, or “comprising” will be understood to imply the inclusion of stated elements but not the exclusion of any other elements.

Further, in the specification, the phrase “in a plan view” means when an object portion is viewed from the above, and the phrase “in a cross-section” means when a cross-section taken by vertically cutting an object portion is viewed from the side.

A display device according to an exemplary embodiment will be described with reference to accompanying drawings.

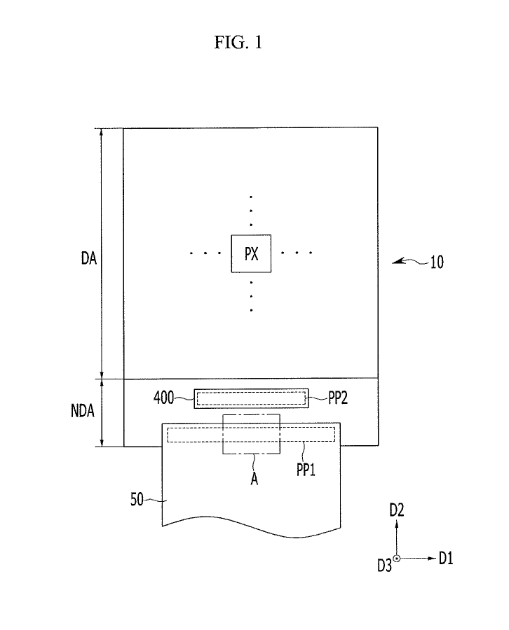

FIG. 1 illustrates a plan view schematically showing a display device according to an exemplary embodiment.

Referring to FIG. 1, a display device according to an exemplary embodiment may include a display panel 10 and a flexible printed circuit board 50 connected to the display panel 10.

The display panel 10 may include a display area DA displaying the image, and a non-display area NDA in which elements and/or wires to generate and/or transmit various signals applied to the display area DA are disposed and positioned outside the display area DA. In FIG. 1, only a lower region of the display panel 10 is shown as the non-display area NDA. In an implementation, a right/left edge of the display panel 10 and/or an upper edge may also correspond to the non-display area NDA.

In the display area DA of the display panel 10, a plurality of pixels PX, e.g., may be disposed in a matrix direction. In the display area DA, the signal lines such as a plurality of gate lines and a plurality of data lines may also be disposed. The plurality of gate lines may mainly extend in a first direction D1 (e.g., a row direction), and the plurality of data lines may mainly extend in a second direction D2 (e.g., a column direction) crossing the first direction D1. Each pixel PX may be connected with a gate line and a data line, thereby being applied with a gate signal and a data signal from these signal lines. In a case of an organic light emitting diode display, in the display area DA, for example, a plurality of driving voltage lines extending in the second direction D2 and transmitting a driving voltage to the pixel PX may be disposed.

In the non-display area NDA of the display panel 10, a first pad portion PP1 may be disposed to receive a signal from outside of the display panel 10. The first pad portion PP1 may be connected to one end of the flexible printed circuit board 50. An anisotropic conductive film may be positioned between the first pad portion PP1 and the flexible printed circuit board 50. The other end of the flexible printed circuit board 50, e.g., may be connected to an external printed circuit board, thereby transmitting a signal such as image data.

A driving device generating and/or processing the various signals to drive the display panel 10 may be positioned at the non-display area NDA of the display panel 10 or the flexible printed circuit board 50, or may be positioned at the external printed circuit board. The driving device may include a data driver applying the data signal to the data line, a gate driver applying the gate signal to the gate line, and a signal controller controlling the data driver and the gate driver.

In an implementation, the data driver may be mounted to a second pad portion PP2 positioned between the display area DA and the first pad portion PP1 in a shape of an integrated circuit chip 400. The anisotropic conductive film may be located between the second pad portion PP2 and the integrated circuit chip 400. In an implementation, the data driver may be mounted to the flexible printed circuit board 50 in an integrated circuit chip shape, thereby being connected to the first pad portion PP1 in a tape carrier package (TCP). In an implementation, the gate driver may be provided in the integrated circuit chip shape. In an implementation, it may be integrated with the non-display area of the left/right edges of the display panel 10. The signal controller may be formed of the integrated circuit chip 400 such as the data driver or a separate integrated circuit chip.

So far, the overall configuration of the display device has been described. Next, the display device according to an exemplary embodiment will be described while focusing on a part where the flexible printed circuit board 50 is connected to the first pad portion PP 1.

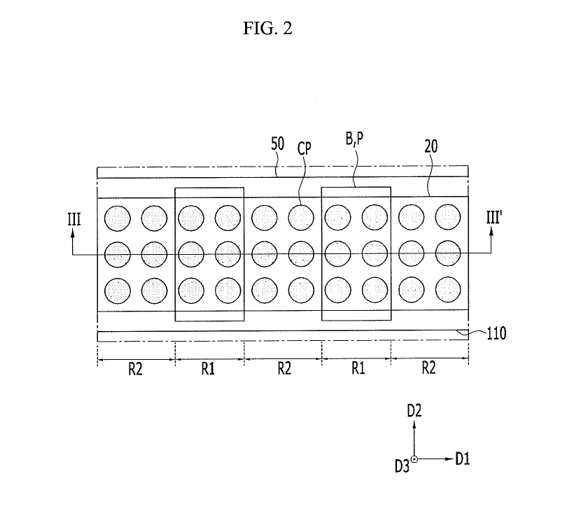

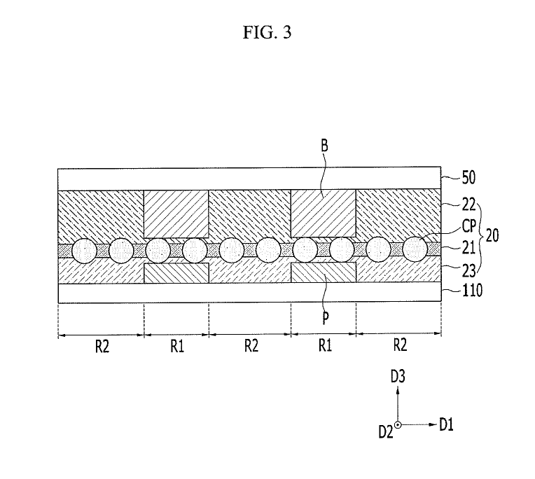

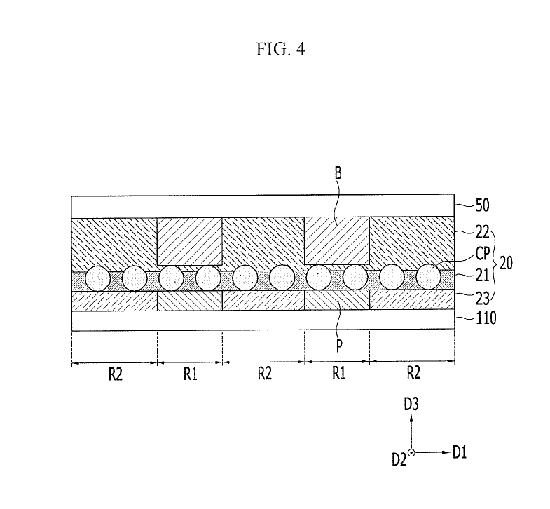

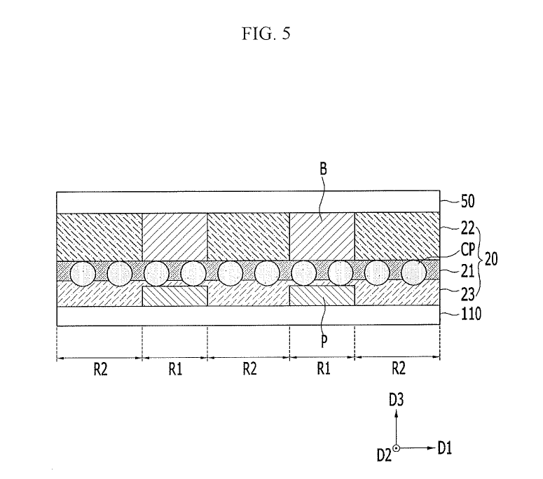

FIG. 2 illustrates an enlarged plan view showing a region A in FIG. 1, FIG. 3 illustrates a cross-sectional view showing an exemplary embodiment taken along a line of FIG. 2, FIG. 4 illustrates a cross-sectional view showing an exemplary embodiment taken along a line of III-III′ FIG. 2, and FIG. 5 illustrates a cross-sectional view showing an exemplary embodiment taken along a line III-III′ of FIG. 2.

Referring to FIG. 2 and FIG. 3, the flexible printed circuit board 50 may be bonded to the first pad portion PP1 through the anisotropic conductive film 20. The anisotropic conductive film 20 may be pressed and cured.

A pad P of the first pad portion PP1 may be positioned on the substrate 110, and the flexible printed circuit board 50 may include a bump B protruded toward the pad P. The bump B of the flexible printed circuit board 50 may be electrically connected to the pad P of the first pad portion PP1 through conductive particles CP of the anisotropic conductive film 20. The bump B and the pad P may each be referred to as an electrode.

In an implementation, the anisotropic conductive film 20 may include three layers, e.g., a supporting layer 21, and a first adhesive layer 22, and a second adhesive layer 23 positioned on and under the supporting layer 21. For example, the first adhesive layer 22 may be on one side of the supporting layer 21 and the second adhesive layer 23 may be on another side of the supporting layer 21. The supporting layer 21 may include the conductive particles CP, e.g., the supporting layer 21 may surround or accommodate the conductive particles CP, and may electrically connect the flexible printed circuit board 50 to the first pad portion PP1. The first and second adhesive layers 22 and 23 may physically connect the flexible printed circuit board 50 to the first pad portion PP1.

In the supporting layer 21, the conductive particles CP may be arranged in a single layer at a predetermined interval, and a position of the conductive particles may be rigidly fixed by the supporting layer 21 (which may be cured prior to being applied to the display device). The adjacent conductive particles CP may be insulated from each other by the supporting layer 21.

The conductive particles CP may be positioned at or in a first region R1 (where the bump B and the pad P face and overlap each other), and may also be positioned at a second region R2 (where the bump B and the pad P do not overlap, e.g., where the bump B and/or the pad P are not present on the substrate 110 or the circuit board 50. In the first region R1, the conductive particles CP may contact the bump B and the pad P that are disposed thereon and thereunder, thereby electrically connection them. Accordingly, the signals transmitted through the flexible printed circuit board 50 may be transmitted to the display panel 10 through the bump B, the conductive particles CP, and the pad P. The conductive particles CP may be isolated in the second region R2. For example, in the second region R2, the conductive particles CP may not contact any of the bumps B or pads P, and do not contact any adjacent conductive particles CP. Accordingly, although the conductive particles CP are present in the second region R2, a short may not be generated between the adjacent bumps B or the adjacent pads P. In an implementation, the conductive particles CP may not be positioned at or present in the second region R2.

The conductive particles CP may be spherical, and may have a diameter that is greater than a thickness of the supporting layer 21 (e.g., in the third direction D3). In an implementation, the conductive particles CP may have a diameter of several micrometers, e.g., about 2 to about 5 micrometers. Accordingly, the conductive particles CP may not be entirely disposed inside the supporting layer 21, and a part thereof may be on the or extend outside of the supporting layer 21. For example, a part of each conductive particle CP may be protruded on or at the upper surface of the supporting layer 21 and a part may be protruded under the lower surface of the supporting layer 21. For example, the conductive particle CP may extend outwardly from each of opposite sides of the supporting layer 21. In an implementation, the conductive particles CP may have a structure such that a metal layer such as nickel, cobalt, gold, silver, and copper is coated on the spherical polymer. In an implementation, the conductive particles CP may have another three-dimensional shape, e.g., other than the spherical shape.

The conductive particles CP in the supporting layer 21 may be substantially arranged with a constant interval between the adjacent conductive particles CP in any direction. For example, the conductive particles CP may be arranged at a uniform interval in the first direction D1 and may also be arranged at a uniform interval in the second direction D2 crossing the first direction D1. This uniform interval may be maintained throughout the first region R1 and the second region R2, because the conductive particles CP that are previously cured or fixed in position when pressing the anisotropic conductive film (AFC) may not be moved within the supporting layer 21 to be fixed.

The first adhesive layer 22 may be positioned at or on the upper surface of the supporting layer 21, and the second adhesive layer 23 may be positioned at or on the lower surface of the supporting layer 21. The first and second adhesive layers 22 and 23 may be formed thinly in the first region R1, and may be thickly formed in the second region R2.

Before the anisotropic conductive film 20 is used to bond the flexible printed circuit board 50 to the first pad portion PP1, the first and second adhesive layers 22 and 23 may be in the non-cured state and may have substantially the same thickness throughout the entire surface of the anisotropic conductive films 20. To bond the flexible printed circuit board 50 to the first pad portion PP1, if the anisotropic conductive film 20 is disposed therebetween and pressure is applied, among the first and second adhesive layers 22 and 23 in the non-cured state, the part that is disposed in the first region R1 may flow and may be pushed into the second region R2. Thus, the first adhesive layer 22 may fill the space between the adjacent bumps B, and the second adhesive layer 23 may fill the space between the adjacent pads P. Accordingly, the conductive particles CP may contact the bump B and the pad P in the first region R1 such that the bump B and the pad P are electrically connected. In the second region R2, the area where the first and second adhesive layers 22 and 23, and the flexible printed circuit board 50, and the first pad portion PP1 are contacted may be increased, thereby increasing the adherence. In an implementation, the first and/or second adhesive layers 22 and 23 in the first region R1 may not be completely pressed out to the second region R2, and a part may remain in the first region R1. For example, as shown in FIG. 3, the first adhesive layer 22 may remain to correspond to the height that the conductive particles CP are protruded from the upper surface of the supporting layer 21, and the second adhesive layer 23 may remain to correspond to the height that the conductive particles CP are protruded from the lower surface of the supporting layer 21.

The supporting layer 21 may be in the cured state before and after applying the anisotropic conductive film 20 to the display device. In an implementation, the first and second adhesive layers 22 and 23 are in the non-cured state before being applied to the display device and in the cured state after being applied to the display device. Accordingly, in the process in which the anisotropic conductive film 20 is applied to the display device and the first and second adhesive layers 22 and 23 are cured, the structure of the supporting layer 21 may be maintained, and it may be difficult for the conductive particles CP included in the supporting layer 21 to flow, thereby maintaining their position. Accordingly, the generation of an undesirable short may be suppressed and a capture rate of the conductive particles CP may be improved, thereby improving the insulating and the connecting reliability. Also, the conductive particles CP, as described above, may be arranged with the uniform interval in the first region R1 and the second region R2.

The supporting layer 21 may be formed of a different material from that of the first and second adhesive layers 22 and 23. For example, when the first and second adhesive layers 22 and 23 are formed of a material that is cured by heat, the supporting layer 21 may be formed of a material having a higher melting point than a curing point of the first and second adhesive layers 22 and 23. Thus, the supporting layer 21 may not flow at a temperature applied to cure the first and second adhesive layers 22 and 23, and the conductive particles CP in the supporting layer 21 may maintain their original position. In an implementation, the supporting layer 21, e.g., may include at least one of a polyimide, polyethylene terephthalate, nylon 6, polyvinylidene fluoride, polycarbonate, polybutylene succinate, and polyethylene.

The first adhesive layer 22 and the second adhesive layer 23 may be formed of a material having an insulating property and adhesion, e.g., a thermosetting resin or a photocurable resin. In an implementation, the first adhesive layer 22 and the second adhesive layer 23 may each independently include, e.g., an epoxy resin layer, an acryl resin layer, or a polyester resin layer.

Referring to FIG. 4, compared with the exemplary embodiment shown in FIG. 3, there is a difference in that the conductive particles CP may be protruded from the supporting layer 21. The conductive particles CP may be protruded on one side, e.g., the upper surface of, the supporting layer 21, and may not be protruded at the other side, e.g., under the lower surface, of the supporting layer 21, or are almost not protruded. In an implementation, the conductive particles CP may not be completely covered by the lower surface of the supporting layer 21 in at least first region R1 to be insulated, but a part may be exposed. Accordingly, in the first region R1, the conductive particles CP may contact the bump B and may also contact the pad P, thereby electrically connecting them.

The conductive particles CP may not be protruded from the lower surface of the supporting layer 21, for the second adhesive layer 23 disposed at the lower surface of the supporting layer 20, and the part disposed at the first region R1 may be completely pushed to the second region R2 when pressing the anisotropic conductive film 20. Accordingly, in the first region R1, the second adhesive layer 23 may not exist or may not be present as shown. On the other hand, the conductive particles CP may be protruded from the upper surface of the supporting layer 21, and the part of the first adhesive layer 22 may exist or may be present in the first region R1 like the exemplary embodiment show in FIG. 3.

Referring FIG. 5, in contrast with the exemplary embodiment shown in FIG. 4, one part of the conductive particles CP may be protruded at one side, e.g., under the lower surface, of the supporting layer 21, and may not be protruded at the other side, e.g., on the upper surface, of the supporting layer 21 as another exemplary embodiment. In the first region R1, the conductive particles CP may contact both the bump B and the pad P, thereby electrically connecting them. In the first region R1, the second adhesive layer 23 may partially remain (due to the protruded part of the conductive particles CP). In an implementation, the first adhesive layer 21 may be completely pushed to the second region R2 when pressing the anisotropic conductive film 20, thereby not existing or no longer being present in the first region R1.

In an implementation, the flexible printed circuit board 50 may be bonded to the first pad portion PP1 was described. In an implementation, the characteristics related to the above-described anisotropic conductive film 20 may be equally applied to the integrated circuit chip 400 bonded to the second pad portion PP2 shown in FIG. 1. In the case according to an exemplary embodiment, the insulating property and the connecting reliability of the anisotropic conductive film 20 may be improved, and the connecting area may be reduced such that the size of the integrated circuit chip 400 may be reduced. Accordingly, chip quantity per wafer may be increased such that the manufacturing cost of the integrated circuit chip 400 may be advantageously reduced. In the present specification, the element such as the flexible printed circuit board 50 or the integrated circuit chip 400 bonded to the pad portions PP1 and PP2 of the display panel 10 through the anisotropic conductive film 20 is referred to as a connection member.

Next, the cross-sectional structure of the region A of FIG. 1 will be described in detail by linking with the cross-sectional structure of the pixel area.

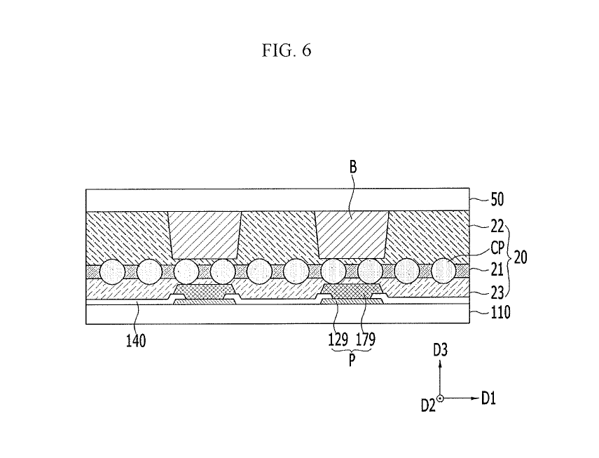

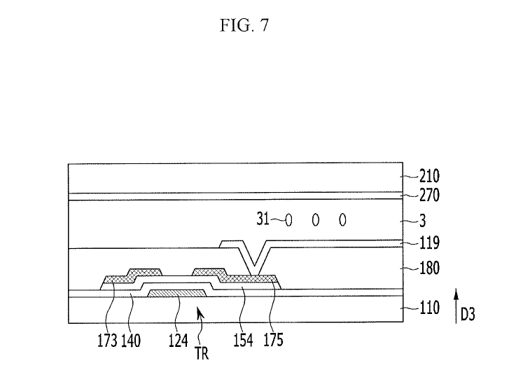

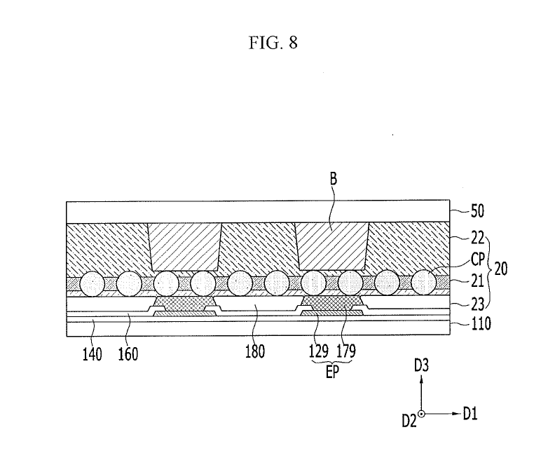

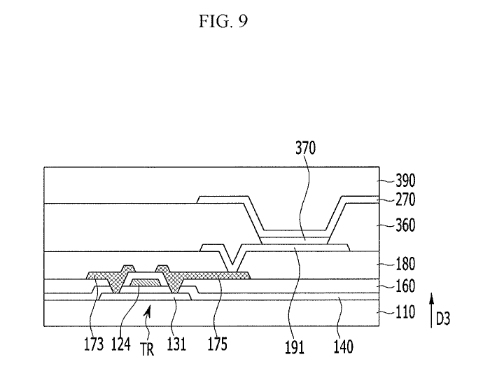

FIG. 6 illustrates a cross-sectional view showing an exemplary embodiment of a region A in FIG. 1, and FIG. 7 illustrates a cross-sectional view showing an exemplary embodiment of a pixel area in FIG. 1. FIG. 8 illustrates a cross-sectional view showing an exemplary embodiment of a region A in FIG. 1, and FIG. 9 illustrates a cross-sectional view showing an exemplary embodiment of a pixel area in FIG. 1.

FIG. 6 and FIG. 7 are to describe a case that the display device is a liquid crystal display as an example, and FIG. 8 and FIG. 9 are to describe a case that the display device is an organic light emitting diode display as an example. In an implementation, the structure of FIG. 6 and the structure of FIG. 8 may be applied regardless of the kind of the display device, and for example, the structure of FIG. 6 may be applied to the organic light emitting diode display.

Referring to FIG. 6 and FIG. 8, compared with FIG. 3, the configuration of the pad P and the layered structure on the substrate 110 are shown in detail. The characteristics of the anisotropic conductive film 20 and the flexible printed circuit board 50 are substantially the same as shown in FIG. 3 such that a repeated detailed description thereof may be omitted.

Referring to FIG. 6 and FIG. 7, a first conductive layer 129 of a pad P and a gate electrode 124 of a transistor TR may be positioned on a substrate 110 such as glass or plastic. The first conductive layer 129 and the gate electrode 124 may be formed by depositing and patterning a conductive material, e.g., copper (Cu), aluminum (Al), silver (Ag), molybdenum (Mo), chromium (Cr), tantalum (Ta), or titanium (Ti), on the substrate 110.

A gate insulating layer 140 may be positioned on the first conductive layer 129 and the gate electrode 124. The gate insulating layer 140 may be formed by depositing an inorganic insulating material such as a silicon oxide and a silicon nitride.

A semiconductor layer 154 of the transistor TR may be positioned on the gate insulating layer 140. In the pixel area, a source electrode 173 and a drain electrode 175 of the transistor TR may be positioned on the semiconductor layer 154, and in the pad region, a second conductive layer 179 may be positioned on the gate insulating layer 140. The second conductive layer 179 may overlap the first conductive layer 129 and may be connected to the first conductive layer 129 through a contact hole formed in the gate insulating layer 140. The second conductive layer 179, the source electrode 173, and the drain electrode 175 may be formed by depositing and patterning a conductive material, e.g., copper (Cu), aluminum (Al), silver (Ag), molybdenum (Mo), chromium (Cr), gold (Au), platinum (Pt), palladium (Pd), tantalum (Ta), tungsten (W), titanium (Ti), or nickel (Ni).

A protection layer 180 (including an organic insulating material and/or an inorganic insulating material) may be positioned on the source electrode 173 and the drain electrode 175, and a pixel electrode 191 (including a transparent conductive material such as indium tin oxide (ITO) or indium zinc oxide (IZO)) may be positioned on the protection layer 180. The pixel electrode 191 may be connected to the drain electrode 175 through a contact hole formed in the protection layer 180, thereby receiving a data signal. A liquid crystal layer 3 including liquid crystal molecules 31 may be positioned on the pixel electrode 191, and an insulating layer 210 sealing the liquid crystal layer 3 along with the substrate 110 may be positioned on the liquid crystal layer 3. The insulating layer 210 may have a substrate shape.

A common electrode 270 generating an electric field to the liquid crystal layer 3 along with the pixel electrode 191 to control an arrangement direction of the liquid crystal molecules 31 may be positioned under the insulating layer 210. An alignment layer may be positioned between the pixel electrode 191 and the liquid crystal layer 3 and between the liquid crystal layer 3 and the common electrode 270. In an implementation, the common electrode 270 may be positioned between the substrate 110 and the liquid crystal layer 3. The common electrode 270 may include the transparent conductive material, e.g., indium tin oxide (ITO) or indium zinc oxide (IZO).

In the pad portion shown in FIG. 6, in the pad P including the first and second conductive layers 129 and 179, the flexible printed circuit board 50 may be bonded through the anisotropic conductive film 20 such that the liquid crystal layer 3, the insulating layer 210, etc., are not positioned on the display area. The protection layer 180 may not be positioned as shown, or may alternatively be positioned between adjacent pads P. A third conductive layer may be positioned on the second conductive layer 179 of the pad P while overlapping and being contacted with the second conductive layer 179, and the third conductive layer may be formed of the same material as the pixel electrode 191 together therewith.

Referring to FIG. 8 and FIG. 9, the semiconductor layer 131 of the transistor TR may be positioned on the substrate 110. The semiconductor layer 131 may include a source region and a drain region, and a channel region between the source region and the drain region. A buffer layer to prevent oxygen and moisture from penetrating may be positioned between the substrate 110 and the semiconductor layer 131.

The gate insulating layer 140 may be positioned on the semiconductor layer 131. The first conductive layer 129 of the pad P and the gate electrode 124 of the transistor TR may be positioned on the gate insulating layer 140. The first conductive layer 129 and the gate electrode 124 may be formed together by depositing and patterning the conductive material such as the metal. In an implementation, the gate insulating layer 140 may be positioned throughout the entire surface of the substrate 110, or the gate insulating layer 140 may be positioned only at the region overlapping the gate conductor such as the first conductive layer 129 and the gate electrode 124.

An interlayer insulating layer 160 may be positioned on the first conductive layer 129 and the gate electrode 124. The second conductive layer 179 of the pad P and the source electrode 173 and the drain electrode 175 of the transistor TR may be positioned on the interlayer insulating layer 160. The second conductive layer 179 may overlap the first conductive layer 129, and may be connected to the first conductive layer 129 through the contact hole formed in the interlayer insulating layer 160. The source electrode 173 and the drain electrode 175 may be respectively connected to the source region and the drain electrode of the semiconductor layer 131 through the contact holes formed in the interlayer insulating layer 160 and the gate insulating layer 140.

The protection layer 180 may be positioned on the source electrode 173 and the drain electrode 175. In the pad region, the protection layer 180 may be positioned between the adjacent pads P as shown. In an implementation, the protection layer 180 may not be positioned in the pad region. The pixel electrode 191 may be positioned on the protection layer 180. The pixel electrode 191 may be connected to the drain electrode 175 through the contact hole formed in the protection layer 180, thereby being applied with the data signal.

A pixel definition 360 may be positioned on the protection layer 180 and the part of the pixel electrode 191. The pixel definition 360 may have an opening overlapping the pixel electrode 191. In the opening of the pixel definition 360, an emission layer 370 may be positioned on the pixel electrode 191, and the common electrode 270 may be positioned on the emission layer 370. The pixel electrode 191, the emission layer 370, and the common electrode 270 may together configure the organic light emitting diode. The pixel electrode 191 may be an anode of the organic light emitting diode, and the common electrode 270 may be a cathode of the organic light emitting diode. An encapsulation layer 390 encapsulating the organic light emitting diode may be positioned on the common electrode 270.

In the pad region, the flexible printed circuit board 50 including bumps B may be positioned on the pad P, and the anisotropic conductive film 20 may be positioned between the pad P and the flexible printed circuit board 50. The anisotropic conductive film 20, as described above, may include a supporting layer 21 including the conductive particles CP, and a first adhesive layer 22 and a second adhesive layer 23 thereunder and thereon. The conductive particles CP positioned to overlap the first adhesive layer 22 and the second adhesive layer 23 between the pad P and the bump B may contact them to be electrically connected, and the conductive particles CP that are not positioned between the pad P and the bump B may be isolated. The conductive particles CP may be uniformly positioned throughout the entire region, and the reliability of the anisotropic conductive film 20 may be ensured.

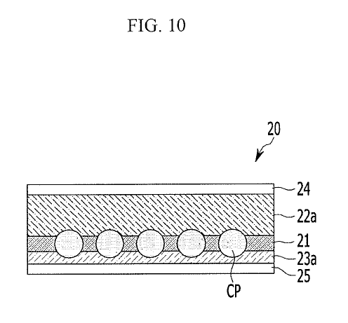

Until now, the exemplary embodiments in which the anisotropic conductive film is applied between the connection member such as the flexible printed circuit board and the pad portion of the display panel to be electrically and physically connected are described. Now, the anisotropic conductive film and the method thereof will be described with reference to FIG. 10 to FIG. 13.

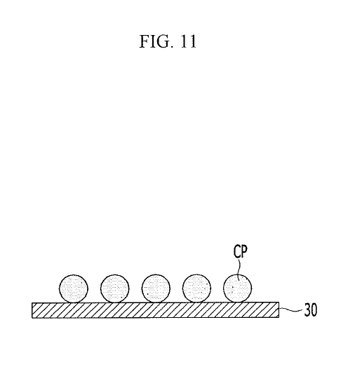

FIG. 10 illustrates a cross-sectional view of an anisotropic conductive film according to an exemplary embodiment, and FIG. 11 to FIG. 14 illustrate process cross-sectional views showing stages in a manufacturing method of an anisotropic conductive film shown in FIG. 10.

Referring to FIG. 10, the anisotropic conductive film 20 according to an exemplary embodiment is shown. The anisotropic conductive film 20 may include a supporting layer 21 including conductive particles CP, a first adhesive layer 22a on the supporting layer 21, and a second adhesive layer 23a under the supporting layer 21. A first release paper 24 may be positioned on the first adhesive layer 22a, a second release paper 25 may be positioned under the second adhesive layer 23a, and the first and second release papers 24 and 25 may be removed when being used. In an implementation, at least one of the first and second release papers 24 and 25 may be omitted. In the anisotropic conductive film 20, the rest of the constituent elements except for the conductive particles CP may be omitted.

The supporting layer 21 may be a polymer layer in a cured state. The supporting layer 21 may be in the cured state, and the conductive particles CP in the supporting layer 21 may be fixed. The supporting layer 21 may be polymerized, and when applying the anisotropic conductive film 20, movement may be difficult under the heating, and accordingly the conductive particles CP in the supporting layer 21 may be difficult to move. The supporting layer 21 may be formed of a material having a higher melting point than the curing point of the first and second adhesive layers 22a and 23b. In an implementation, the supporting layer 21 may include at least of, e.g., polyimide, polyethylene terephthalate, nylon 6, polyvinylidene fluoride, polycarbonate, polybutylene succinate, or polyethylene.

The first adhesive layer 22a on the supporting layer 21 and the second adhesive layer 23a under the supporting layer 21 may be the resin layers in the non-cured state. For example, the first adhesive layer 22a and the second adhesive layer 23a may be a thermosetting resin layer or a light-curing resin layer. The first adhesive layer 22a and the second adhesive layer 23a may be a polymerized type of resin layer including an epoxy compound or an acrylate compound, and a polymerization initiator, and the polymerization initiator may be an ion polymerization initiator or a radical polymerization initiator. The first adhesive layer 22a and the second adhesive layer 23a may be formed of same materials or different materials from each other. At least one of the first adhesive layer 22a and the second adhesive layer 23a may be the thermosetting resin such as the epoxy resin, a polyester resin, a bismaleimide resin, and a cyanate resin, and may be in a semi-cured state. In an implementation, the first adhesive layer 22a may be thicker than the second adhesive layer 23a.

FIG. 11 to FIG. 14 illustrate views showing stages in a process of manufacturing the above-described anisotropic conductive film 20.

Referring to FIG. 11, conductive particles CP may be arranged at a uniform interval in a single layer on a transfer layer 30. In an implementation, the uniform arrangement of the conductive particles CP on the transfer layer 30 may be realized by, e.g., stretching the transfer layer 30 monoaxially or biaxially after arranging the conductive particles CP in the single layer on the transfer layer 30. In an implementation, the uniform arrangement of the conductive particles CP may be realized by filling the conductive particles CP in grooves of a mother substrate in which the grooves are formed with the uniform interval, and transferring the conductive particles CP arranged in the grooves on the transfer layer 30.

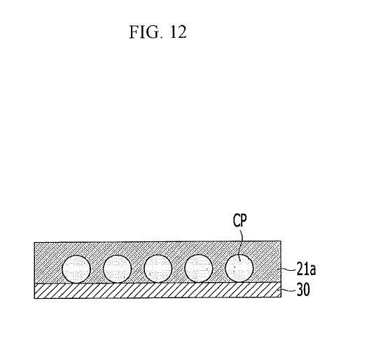

Referring to FIG. 12, a resin may be coated on the transfer layer 30 in which the conductive particles CP are arranged at the uniform interval to form a resin layer 21a in which the conductive particles CP are impregnated, and the resin layer 21a may be cured. Accordingly, the conductive particles CP disposed on the transfer layer 30 may be transferred in the resin layer 21a and may be fixed while maintaining the uniform interval in the cured resin layer 21a. Next, the transfer layer 30 may be separated from the resin layer 21a. The conductive particles CP may be positioned in the resin layer 21a such that they are completely enclosed by the resin layer 21a. Some conductive particles CP may be partially exposed outside the surface of the resin layer 21a. For example, the part of the conductive particles CP, which had been in contact with the transfer layer 30, may not be enclosed by the resin layer 21a, e.g., may be exposed. In an implementation, the thickness of the resin layer 21a may be larger than the diameter of the conductive particles CP, or they may be almost the same.

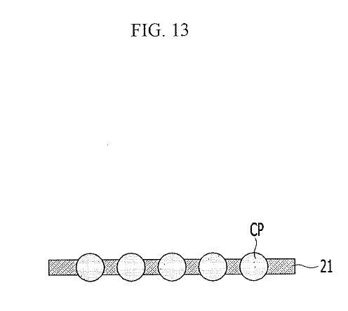

Referring to FIG. 13, both side surfaces of the resin layer 21a in the cured state may be etched to form the supporting layer 21 in which a part of the conductive particles CP is exposed. Accordingly, the thickness of the supporting layer 21 may be smaller than the diameter of the conductive particles CP. The conductive particles CP may be exposed to all be protruded from both the upper surface and the lower surface of the supporting layer 21. In an implementation, the upper surface (the surface that is not contacted with the transfer layer 30 in FIG. 12) of the resin layer 21a may only be etched such that the conductive particles CP may only be protruded from the upper surface of the supporting layer 21.

When the conductive particles CP are disposed inside the resin layer 21a, the resin layer 21a may be in the cured state, and although the pressure may be applied during the usage of the anisotropic conductive layer, the conductive particles CP may not be contacted with the electrodes to be electrically connected, but may be insulated by the resin layer 21a. As the conductive particles CP are exposed outside the resin layer 21a by etching the resin layer 21a, the conductivity in the direction of the thickness of the anisotropic conductive layer may be ensured while fixing the conductive particles CP in the supporting layer 21. In an implementation, as the etching of the resin layer 21a to expose the conductive particles CP, e.g., the dry etching such as reactive ion etching may be used.

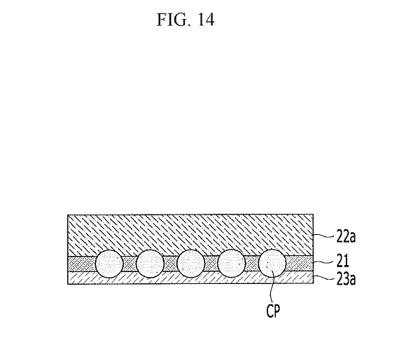

Referring to FIG. 14, the first adhesive layer 22 may be formed on the upper surface of the supporting layer 21 in which the part of the conductive particles CP is exposed, and the second adhesive layer 23 may be formed on the lower surface. The first and second adhesive layers 22 and 23 may be formed, e.g., by laminating a non-cured resin layer or coating the non-cured resin to the supporting layer 21. When being laminated, the non-cured resin layer may be formed on release papers 24 and 25 shown in FIG. 10, thereby being laminated on the supporting layer 21 along with the release papers 24 and 25.

In the above-formed anisotropic conductive film 20, the conductive particles CP may not be moved within the supporting layer 21, but rather may be fixed with the constant interval, and this may be equally maintained after being pressed or heat-pressed to connect the connection member as well as before using the anisotropic conductive film 20.

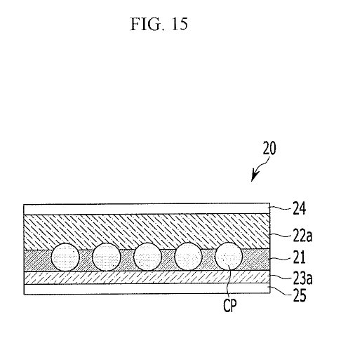

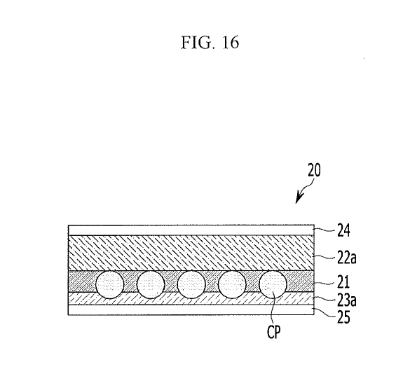

The anisotropic conductive film 20 shown in FIG. 10 may be applied to the display device shown in FIG. 3. The anisotropic conductive film applied to the display device shown in FIG. 4 and FIG. 5 will be described with reference to FIG. 15 and FIG. 16.

FIG. 15 and FIG. 16 illustrate cross-sectional views of an anisotropic conductive film according to an exemplary embodiment.

Referring to FIG. 15, the anisotropic conductive film 10 that may be applied to the display device shown in FIG. 4 is shown. Like the exemplary embodiment shown in FIG. 10, the anisotropic conductive film 20 may include the supporting layer 21 including the conductive particles CP, the first adhesive layer 22a on the supporting layer 21, and the second adhesive layer 23a under the supporting layer 21. The first release paper 24 may be positioned on the first adhesive layer 22a, and the second release paper 25 may be positioned under the second adhesive layer 23a.

Differently from the exemplary embodiment shown in FIG. 10 in which the conductive particles CP are protruded from both of the upper surface and the lower surface of the supporting layer 21, in the present exemplary embodiment, the conductive particles CP may be protruded only from the lower surface of the supporting layer 21. This structure may be formed, e.g., by etching the resin layer 21a shown in FIG. 12 and FIG. 13 to etch only the upper surface of the resin layer 21a in the process of forming the supporting layer 21, and by forming the first adhesive layer 22 on the surface of the supporting layer 21 where the conductive particles CP are protruded and the second adhesive layer 23 on the surface of the supporting layer 21 where the conductive particles CP are protruded. When only one surface of the resin layer 21a is etched, the portion of the conductive particles CP may be covered by the adhesive layer 22 to be in the non-exposed state. Even so, in the actual application, e.g., in the first region R1 shown in FIG. 4, the part of the supporting layer 22 that may be between the conductive particles CP and the pad P may locally flow by the pressure and the heating applied when pressing the anisotropic conductive film 10 and then may be removed between the conductive particles CP and the pad P, thereby the conductive particles CP may be directly contacted with the pad P.

Referring to FIG. 16, the anisotropic conductive film 10 that may be applied to the display device shown in FIG. 5 is shown. As opposed to the anisotropic conductive film 20 shown in FIG. 15, the conductive particles CP are protruded from the upper surface of the supporting layer 21 formed with the first adhesive layer 22a, however the conductive particles CP are not protruded from the lower surface of the supporting layer 22. This structure may be formed, e.g., by etching only the upper surface of the resin layer 21a when etching the resin layer 21a shown in FIG. 12 and FIG. 13 to form the supporting layer 21 and by forming the first adhesive layer 22a at the surface of the supporting layer 21 where the conductive particles CP are protruded. The part of the supporting layer 21 that may cover the conductive particles CP at the not-etched surface may be locally moved by the heat and the pressure, and accordingly the bump B and the conductive particles CP may be directly contacted in the first region R1 shown in FIG. 5.

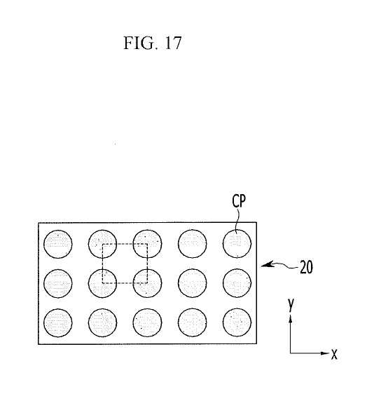

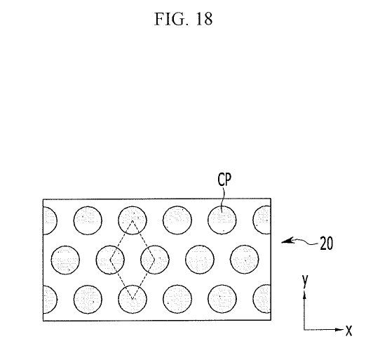

FIG. 17 and FIG. 18 each illustrate a plan view showing an arrangement of conductive particles according to an exemplary embodiment.

Referring to FIG. 17, the conductive particles CP of the anisotropic conductive film 20 may be disposed in a rectangular shape. For example, the conductive particles CP may be disposed with the first interval in the x-axis direction, and may also be disposed with the same first interval in the y-axis direction perpendicular to the x-axis direction. As another example, referring to FIG. 18, the conductive particles CP may be disposed in a rhombus shape. For example, the conductive particles CP may be disposed with the first interval in the x-axis direction, and may be disposed with a second interval (different from the first interval) in the y-axis direction perpendicular to the x-axis direction. The interval between the conductive particles CP may be determined by considering the pitch and the width of the electrodes to be applied. The uniform arrangement of the conductive particles CP in the anisotropic conductive film 20 may be maintained before and after the usage of the anisotropic conductive film 20.

By way of summation and review, in a process of bonding the integrated circuit chip or the flexible printed circuit board to the pad portion through the anisotropic conductive film, a pressure may be applied to the anisotropic conductive film. In this case, the conductive particles may flow in the resin such that the insulation in the surface direction of the film and/or the conductivity in the thickness direction of the film may be deteriorated.

The embodiments may provide a display device including an anisotropic conductive film in which the flow of the conductive particles may be reduced and/or prevented.

According to exemplary embodiments, even if the anisotropic conductive film is pressed, the flow of the conductive particles may be reduced and/or prevented, and the conductivity in the thickness direction and the insulating in the surface direction of the anisotropic conductive film may be improved in the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display device, comprising:
a pad portion positioned on a substrate, the pad portion including a plurality of pads;
an anisotropic conductive film positioned on the pad portion; and
a connection member bonded to the pad portion through the anisotropic conductive film, the connection member including a plurality of bumps,
wherein the anisotropic conductive film includes:
a supporting layer including a plurality of conductive particles, each of the conductive particles having a part protruded from a first surface of the supporting layer and a part protruded from a second surface of the supporting layer;
a first adhesive layer contacting the first surface of the supporting layer and the part of each conductive particle protruding from the first surface; and
a second adhesive layer contacting the second surface of the supporting layer and the part of each conductive particle protruding from the second surface, and
wherein at least one of the first adhesive layer and the second adhesive layer is positioned at both of a first region of the display device and a second region of the display device, the first region being a region in which the pads and the bumps are overlapped and the second region being a region in which the pads and the bumps are not overlapped.

2. The display device as claimed in claim 1, wherein the supporting layer is formed of a material that is different from a material of the first adhesive layer and a material of the second adhesive layer.

3. The display device as claimed in claim 2, wherein the supporting layer includes at least one of polyimide, polyethylene terephthalate, nylon 6, polyvinylidene fluoride, polycarbonate, polybutylene succinate, or polyethylene.

4. The display device as claimed in claim 1, wherein a melting point of the supporting layer is higher than a curing point of the first adhesive layer and a curing point of the second adhesive layer.

5. The display device as claimed in claim 1, wherein an interval between the conductive particles adjacent to one another in a first direction is uniform in the first region and the second region.

6. The display device as claimed in claim 5, wherein an interval between the conductive particles adjacent to one another in a second direction is uniform in the first region and the second region, the second direction crossing the first direction.

7. The display device as claimed in claim 5, wherein the plurality of conductive particles are arranged as a rectangle or a rhombus in a plan view.

8. The display device as claimed in claim 1, wherein a diameter of the plurality of conductive particles is larger than a thickness of the supporting layer.

9. The display device as claimed in claim 1, wherein a part of the first adhesive layer in the first region is thinner than a part of the first adhesive layer in the second region.

10. The display device as claimed in claim 1, wherein a part of the second adhesive layer in the first region is thinner than a part of the second adhesive layer in the second region.

11. A method for manufacturing an anisotropic conductive film, the method comprising:
arranging conductive particles at a non-cured resin layer;
curing the resin layer to fix the conductive particles in the cured resin layer; and
etching the cured resin layer to form a supporting member such that a part of the conductive particles are exposed.

12. The method as claimed in claim 11, wherein etching the cured resin layer includes exposing the part of the conductive particles on at least one surface of the supporting member.

13. The method as claimed in claim 11, wherein the etching the cured resin layer includes reactivity ion etching.

14. The method as claimed in claim 11, wherein the supporting layer includes at least one of polyimide, polyethylene terephthalate, nylon 6, polyvinylidene fluoride, polycarbonate, polybutylene succinate, or polyethylene.

15. The method as claimed in claim 11, further comprising forming an adhesive layer on at least one surface of the supporting member.

16. The method as claimed in claim 15, wherein the adhesive layer is formed to be in contact with the exposed part of the conductive particles.

17. The method as claimed in claim 15, wherein forming the adhesive layer includes laminating a non-cured resin layer on the supporting member.

18. The method as claimed in claim 15, wherein the adhesive layer is formed of a material that is different from a material of the supporting layer.

19. The method as claimed in claim 15, wherein a melting point of the supporting layer is higher than a curing point of the adhesive layer.

20. The method as claimed in claim 11, wherein the supporting layer is formed to have a thickness that is smaller than a diameter of each conductive particle.
